(19) United States
(12) Patent Application Publication
(10) Pub. No.: US 2007/0008038 A1
(43) Pub. Date: Jan. 11, 2007

(54) Power amplifier arrangement, particularly for mobile radio, and method for determining a performance parameter

(76) Inventors: Bernd-Ulrich Klepser, Starnberg (DE); Michael Asam, Inchenhofen (DE); Markus Zannoth, Neubiberg (DE)

Correspondence Address: ESCHWEILER & ASSOCIATES, LLC;NATIONAL CITY BANK BUILDING, 629 EUCLID AVE., SUITE 1000, CLEVELAND, OH, 44114, US

(21) Appl. No.: 11/476,461

(22) Filed: Jun. 28, 2006

(30) Foreign Application Priority Data
Jun. 28, 2005 (DE) DE102005030121.5
Dec. 22, 2005 (DE) DE102005061572.4

(51) Int. Cl. H03F 1/38; H03F 3/04; H04L 25/49; H04L 27/08; H04K 1/02; H04L 25/03

(52) U.S. Cl. 330/291; 330/289; 375/297; 375/345

(57) ABSTRACT

A power amplifier arrangement includes a power amplifier with an input for a radio-frequency signal and an output for delivering a second radio-frequency signal. The second radio-frequency signal has a current and a voltage. A second element is configured to deliver a first signal derived from the current of the second radio-frequency signal. Furthermore, a first element is provided to deliver a second signal derived from the voltage of the second radio-frequency signal. An evaluating circuit detects in-phase components of the first and the second signal. As a result, in-phase current and voltage components can be detected together which produce the active power of the second radio-frequency signal by multiplication.

### REFERENCE TO RELATED APPLICATIONS

This application claims the benefit of the priority date of German applications DE 10 2005 030 121.5, filed on Jun. 28, 2005 and DE 10 2005 061 572.4 filed Dec. 22, 2005, the contents of which are herein incorporated by reference in their entirety.

### FIELD OF THE INVENTION

The invention relates to a power amplifier arrangement, particularly for mobile radio. The invention also relates to a method for determining a performance parameter, particularly of a power amplifier.

### BACKGROUND OF THE INVENTION

The increasing use of wireless communication makes it necessary to use the available frequencies in an optimum fashion. For this reason, many mobile radio standards demand the capability of adjusting the transmitting power of mobile communication devices. It is required that the transmitting power of mobile communication devices be predetermined accurately, on the one hand, and on the other hand, maintained within a narrow tolerance. In addition, amplifiers in the transmitting output stage should operate as linearly as possible and not generate any distortions which lead to intermodulation products and thus to an undesired widening of the frequency spectrum. These requirements allow the available frequency space to be utilized as efficiently as possible and, at the same time, interference in adjacent channels to be minimized during a transmitting process.

In practice, however, the output power of a power amplifier of mobile communication systems varies. The variation is dependent on the temperature of the power amplifier, the current supply voltage, the transmitting frequency, the input power and the load impedance. It is especially the load impedance which in some cases changes frequently and can be dependent on the spatial environment of the mobile communication device, among other things. For this reason, a changing load impedance, in particular, can negatively influence the output power of a power amplifier and its linearity.

To be able to correct the fluctuations in the output power or in the linear transfer characteristic of a power amplifier, it is appropriate to detect the radiated transmitting power and to compare it subsequently with a nominal value. In the case of a deviation, the output power of the power amplifier of the mobile communication device is correspondingly corrected.

One possibility for determining the output power lies in the use of a so-called directional coupler which is connected between the output of the power amplifier and the antenna. In this arrangement, the directional coupler detects the advancing electrical wave, from which the power delivered can be determined. However, the installation of a directional coupler is a costly measure and in addition, also generates losses due to its insertion loss. As a result, the efficiency of the power amplifier becomes worse. In addition, the results determined by the directional coupler only make it possible to estimate whether an amplifier of the transmitting output stage is operated within a linear range of its characteristic.

As an alternative possibility for detecting the output power, a peak rectifier which uses the current amplitude of the output voltage of the power amplifier may be employed. Under certain circumstances, however, it is not possible to detect the actual power delivered in the case of direct detection of the output voltage. If, for example, there is a mismatch between the output of the power amplifier and the elements connected thereto, a wrong output value can be detected. In addition, the peak value of the voltage is influenced by so-called harmonics which, in turn, are greatly dependent on the load impedance and thus on the mismatch. These harmonics are also influenced by the direct linear transfer characteristic of the power amplifier. In consequence, a trustworthy result for estimating an output power or a measure for determining the linearity of the amplifier is not guaranteed under all conditions.

### SUMMARY OF THE INVENTION

The following presents a simplified summary of the invention in order to provide a basic understanding of some aspects of the invention. This summary is not an extensive overview of the invention, and is neither intended to identify key or critical elements of the invention nor to delineate the scope of the invention. Rather, the purpose of the summary is to present some concepts of the invention in a simplified form as a prelude to the more detailed description that is presented later.

According to one embodiment of the invention, it is provided to detect and evaluate both the current and the voltage of the radio-frequency signal jointly in a power amplifier for delivering a radio-frequency signal having a current and a voltage. For this purpose, the arrangement comprises, in addition to the power amplifier, a first element which is configured to deliver a first signal derived from the voltage of the radio-frequency signal delivered by the power amplifier. A second element is configured to deliver a second signal derived from the current of the radio-frequency signal, essentially flowing at the same time as the voltage. The first and the second element are coupled to an evaluating circuit that combines the signals delivered by the first and second element to form a joint evaluation and, in dependence thereon, delivers an evaluation signal. This allows a decision to be made about various performance parameters of the power amplifier arrangement. It is thus possible to determine a parameter for determining a performance capability of the amplifier by simple means using the power amplifier arrangement.

Thus it is possible, for example, to determine whether the power amplifier is operating in a linear range or in a nonlinear range of its characteristic by essentially concurrently detecting the output current and the output voltage of the power amplifier. Another combination comprises configuring the evaluating circuit to multiply in-phase components of the first or second derived signal, respectively. This is equivalent to an in-phase multiplication of the signals representing the current and the voltage of the radio-frequency signal of the power amplifier. In this manner, the active power of the power amplifier delivered is determined directly. Thus, the output power of the power amplifier can be adapted rapidly and flexibly to changing external conditions.

Thus, a signal is amplified, the amplified signal having a voltage and a current. The current and voltage are detected at approximately the same points in time and the results are combined with one another. The combining allows a performance parameter to be generated, for example, an active power due to in-phase multiplication of the two results. Another possibility comprises determining limit-value transgressions by comparing the results with different threshold values.

In one embodiment of the invention, the power amplifier comprises a transistor output stage with a control input. This forms the input to the power amplifier. The second element is configured to detect a current delivered by the transistor output stage and the first element is configured to detect a voltage present at an output of the transistor output stage essentially at the same time. In this arrangement, the second element comprises, for example, a transistor which is connected with its control terminal to the input of the power amplifier for delivering a current derived from the power amplifier.

In one embodiment, the first element is configured to compare the signal derived from the detected voltage with a first threshold value. The second element comprises a detector configured to compare the signal derived from the current with a second threshold value. When the signal drops below the first threshold value and/or exceeds the second threshold value, it is thus possible to determine whether the power amplifier is operating in a nonlinear range. In other words, comparison circuits in the first and second element provide a detector for determining the linearity of the power amplifier.

In another embodiment of the invention, the power amplifier arrangement comprises a power amplifier with an input configured to supply a first radio-frequency signal, and an output configured to deliver a second radio-frequency signal. The second radio-frequency signal has a current and a voltage. The power amplifier arrangement comprises a first element configured to deliver a first signal that is derived from the voltage of the second radio-frequency signal. Furthermore, a second element is configured to deliver a second signal derived from the current of the second radio-frequency signal. In addition, the arrangement comprises a detector circuit configured to detect essentially in-phase components of the first and the second signal. The detector circuit is coupled to the first and the second element.

In one embodiment, the power amplifier arrangement comprises a means to concurrently evaluate both the current voltage and the current current of the radio-frequency signal delivered by the power amplifier. In this arrangement, the current and voltage of the second radio-frequency signal are advantageously multiplied in phase as a result of which the true active power generated, which is delivered by the power amplifier, can be determined. The in-phase multiplication of the radio-frequency current and of the radio-frequency voltage of the second radio-frequency signal provides the active power delivered. In one example, the power amplifier arrangement is also independent of the load impedance connected to the output of the power amplifier. This means that the arrangement according to one embodiment of the invention with the detector circuit indicates the correct active power even in the case of a mismatch and thus the correct level of the second radio frequency signal is reproduced.

In one embodiment of the invention, the first element comprises AC coupling configured to detect the radio-frequency voltage component of the second radio-frequency signal. In a further embodiment, the second element contains a transistor, the control terminal of which is connected to the input of the power amplifier. As a result, the transistor can generate a voltage or also a current signal that is derived from the current of the second radio-frequency signal.

In another embodiment of the invention, the detector circuit comprises a frequency converter. The frequency converter is connected to the second element with a first signal input and to the first element with a second signal input. Both the signal delivered by the first and by the second element is advantageously converted in the frequency converter and then filtered. Thus, the radio-frequency components are suppressed.

In the case of a conversion of signals that are derived from a current or a voltage of the second radio-frequency signal, in-phase components generate the active power. These are advantageously mixed in the frequency converter to form a DC signal component due to the multiplication.

In a further embodiment of the invention, a low-pass filter is provided which is configured to suppress higher frequency components. During a conversion, phase-shifted components are converted into twice the fundamental frequency and can be easily suppressed by the following low-pass filter. The low-pass filter can also be advantageously integrated in the converter. In an alternative embodiment, an evaluating circuit is used that suppresses, or does not take into consideration, the higher-frequency components. In one embodiment, the evaluating circuit comprises an analog/digital converter which does not take into consideration higher frequency components during the conversion. In one embodiment, a component of the voltage of the second radio-frequency signal is formed directly for the multiplication. In this embodiment, the first element is used to detect a part of the voltage of the second radio-frequency signal.

Thus the active power actually delivered is detected by means of the power amplifier arrangement specified and, in addition, a mismatch is taken into consideration. The detector can be advantageously completely integrated in the power amplifier. In addition, a simple construction as an integrated circuit in a semiconductor body is possible.

In another embodiment of the invention, the detector circuit comprises a differential amplifier with a first and a second transistor. The first terminals in each case are connected to the second element via a common low end. The second element is constructed for supplying a supply current to the differential amplifier, the supply current being derived from the current of the radio-frequency signal delivered by the power amplifier.

In a further embodiment, a Gilbert mixer is provided as a detector circuit. This has the advantage of processing only voltage signals so that the signal derived from the current or from the voltage, respectively, can be applied in each case to the inputs of the mixer.

In the case of large output powers, it can happen that the voltage amplitude becomes large at the power amplifier output. As a result the output current of the radio-frequency signal can be reduced. In one embodiment of the invention, to improve the detection characteristic, a rectifier is provided which is configured to detect a threshold value and, in dependence thereon, deliver a potential to the detector circuit.

In another embodiment, a tap is additionally provided between the second element and the detector circuit that is connected to a further rectifier circuit configured to detect a threshold value. The output of the rectifier circuit is connected to an input of an operational amplifier, the other input of which is coupled to the output of the power amplifier and, in one example, to the output of the power amplifier via a further rectifier circuit, constructed in the same manner. An output of the operational amplifier leads to a tap between the first element and the detector circuit.

To determine an active power, for example, an active power of a power amplifier, a signal is provided and amplified. A signal is then generated that is derived from the current of the amplified signal. At the same time, a second signal is additionally generated that is derived from the voltage of the amplified signal. Following this, the signals generated in this manner are multiplied by one another in phase which results in a result proportional to the active power delivered. Thus, the active power actually delivered is detected and any mismatch which may be occurring at the same time is taken into consideration.

The method according to the invention, which can be performed by simple means, can be used for determining the active power, particularly in power amplifiers.

In one embodiment of the invention, a current can moreover be advantageously generated which is derived from the current of the amplified radio-frequency signal. Similarly, a voltage can be derived from the voltage of the amplified signal. In one embodiment, a voltage component of the amplified signal can also be used directly.

In one embodiment of the method, the step of multiplying is effected by a frequency conversion or by mixing the first and second signal, respectively, and thus mixing the detected current and the detected voltage. Following this, the DC signal component in the mixed signal is determined.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

In the text which follows, the invention will be explained in greater detail by means of a number of exemplary embodiments and referring to the figures. Functionally and operationally identical components carry identical reference symbols.

FIG. 1A is a general block diagram illustrating a first exemplary embodiment of the invention,

FIG. 1B is a block diagram illustrating a second exemplary embodiment of the invention,

FIG. 1C is a control loop with a power amplifier arrangement according to a third exemplary embodiment of the invention,

FIG. 2 is a block diagram of a power amplifier arrangement according to a fourth exemplary embodiment of the invention,

FIG. 3 is a fifth exemplary embodiment of a power amplifier arrangement according to the invention,

FIG. 4 is a sixth exemplary embodiment of the power amplifier arrangement,

FIG. 5 is a seventh exemplary embodiment of the power amplifier arrangement,

FIG. 6 is an eighth exemplary embodiment of the power amplifier arrangement,

FIG. 7 is a ninth exemplary embodiment of the power amplifier arrangement,

FIG. 8 is a tenth exemplary embodiment of the power amplifier arrangement, and

FIG. 9 is an eleventh exemplary embodiment of the power amplifier arrangement.

### DETAILED DESCRIPTION OF THE INVENTION

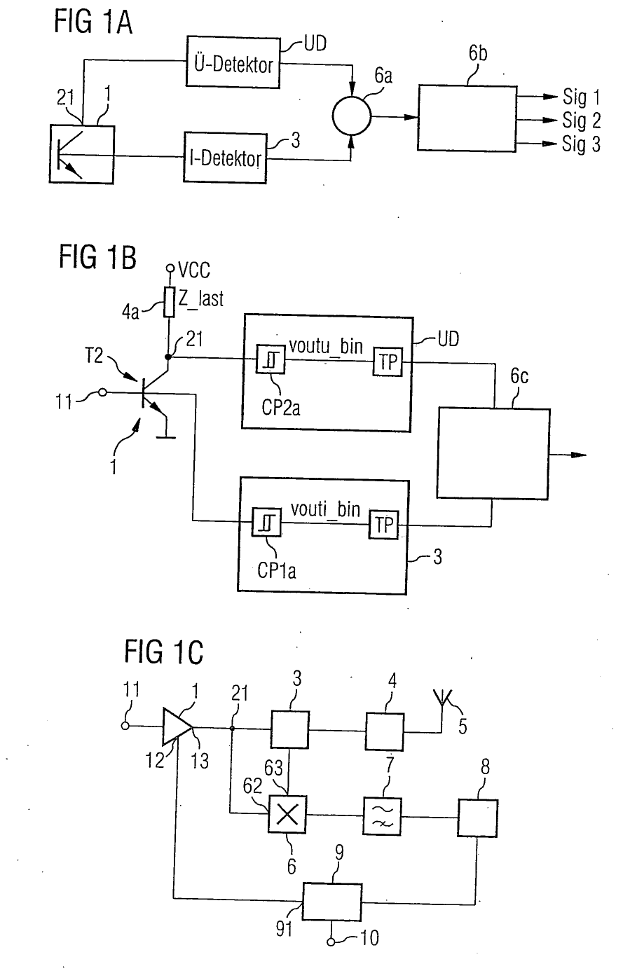

FIG. 1A shows a general block diagram according to one embodiment of the invention. A power amplifier 1 is part of a transmit path. It contains further components and circuits which are not shown here for reasons of clarity. This includes, for example, a baseband unit which provides a baseband for further signal processing, and a mixer for converting to the carrier signal. Similarly, various supply circuits are provided in the transmit path, for example, for setting the operating point of the power amplifier.

The output of the power amplifier 1 is connected to a tap 21 for delivering a part of the radio-frequency signal to a voltage detector UD. The detector is configured to determine an output voltage of the radio-frequency signal delivered by the power amplifier 1. Furthermore, the circuit contains a current detector 3 that evaluates the output current delivered by the power amplifier 1. Voltage detector UD and current detector 3 are configured to concurrently detect current and voltage of the radio-frequency signal delivered by the power amplifier 1 in each case.

The detected signals are delivered by the voltage detector UD and the current detector 3 to an evaluating circuit 6a which combines the two values with one another and from these delivers an evaluation signal to the circuit 6b. Depending on the embodiment, the combining or evaluating circuit, respectively, comprises, for example, a highly linear multiplier for measuring active power, a gate for digital evaluation of linearity or also simple forwarding of the signals. The combining performed in the evaluating circuit 6a and the generation of an evaluation signal enable the circuit 6b to perform an analysis of an operating parameter of the power amplifier 1. Depending on the operating parameter, the circuit 6b can then deliver various control signals SIG1 to SIG3 to the further components of the transmit path, and thus change the settings for the operation of the power amplifier 1.

For example, it is possible to determine via the evaluation signal from the evaluating circuit 6a, whether the power amplifier 1 is located in a linear range of its characteristic. If so, in one example, no further measures are necessary. If, in contrast, the evaluation signal indicates that the amplifier 1 is operated in a nonlinear range of its characteristic, signals Sig1, Sig2 or Sig3 are generated and thus the operating parameters of the amplifier 1 are changed. For example, the amplifier 1 can be moved out of the nonlinear range back into a linear range of its characteristic by changing its operating point setting. This makes it possible to reduce the distortion characteristic of the power amplifier.

FIG. 1B shows a simplified embodiment for detecting and measuring the linearity characteristic of the power amplifier 1. In this example, which is in no way restrictive, the power amplifier 1 is indicated by a simple bipolar transistor T2. The radio frequency signal to be amplified is present at its control input 11 of the bipolar transistor T2. The bipolar transistor T2 is connected between a supply potential terminal VCC and a reference potential terminal. Between its collector terminal and the supply potential terminal VCC there is a load 4a for generating the amplified radio-frequency signal. A tap 21 between the collector terminal and the load 4a is connected to the voltage detector UD. The input of the current detector 3 is connected to the control terminal 11 of the bipolar transistor T2 of the power amplifier 1.

Current detector 3 and voltage detector UD in each case comprise a threshold comparator CP1a, CP2a which compare the signals present at the input with a threshold value. The first comparator CP1a of the current detector 3 comprises a current input. The threshold detector CP2a of the voltage detector UD has a voltage input. At the output, the two threshold detectors are coupled to an evaluating circuit 6c via a low-pass filter TP. In the present case, this presents a logical “OR gate”.

To detect nonlinearity of the transistor T2, and thus a nonlinear gain characteristic of the power amplifier 1, the saturation voltage of the transistor and its saturation current can be detected. When a linearity limit is reached, therefore, either the saturation voltage or a maximum predetermined current through the transistor T2 is reached. For this purpose, the current detector 3 and especially the threshold detector CP1a are configured to detect a maximum current. When this current is exceeded, it outputs a logical signal vouti_bin at its output. Accordingly, the threshold comparator CP2a generates the logical signal voutu_bin by comparing the output voltage of the transistor T2 with a threshold value. In the case of a transgression of one of the two threshold values, the transistor begins to operate in a nonlinear range of its characteristic and the corresponding threshold detector delivers a signal with a high level which represents a logic “1”.

The two signals are supplied to the logic gate of the evaluating circuit 6c. This gate is constructed as logical OR gate. As a result, the information obtained in this example only says whether the transistor of the power amplifier is operating in a range of its nonlinearity but not whether current or voltage are decisive for this nonlinearity. The series-connected low-pass filters smooth the signal in order to obtain a DC voltage at the output.

FIG. 1C shows a control loop with a power amplifier arrangement according to another embodiment of the invention. In this arrangement, a power amplifier 1 is provided which has an input 11 for supplying a radio-frequency signal. The gain of the power amplifier 1 can be adjusted via a corresponding control signal at its control input 12. At its output 13, it outputs an amplified radio-frequency signal which has a voltage and a current. The output of the power amplifier 1 is connected to a current detector 3. This detects the current in the second radio-frequency signal delivered by the power amplifier and generates from this a derived signal. At the same time, the radio-frequency signal amplified by the power amplifier 1 is supplied to a matching network 4, the output of which, in turn, is connected to the antenna 5.

In addition, a tap 21 is provided between the current detector 3 and the output 13 of the power amplifier 1. This tap is used for picking up a voltage component of the radio-frequency signal delivered by the power amplifier 1. The tap 21 is connected to an input 62 of a frequency converter 6. A second input 63 of the frequency converter 6 is connected to the current detector 3. At its output, the converter 6 is connected to an analog/digital converter 8, via a low-pass filter 7. The digitized signal delivered via the frequency converter 6 is supplied to the control circuit 9. Together with a control signal at the correcting input 10, this circuit generates an adjustment signal and delivers it at its output 91 which is connected to the correcting input 12 of the power amplifier.

When the power amplifier is in operation, a transmitting power of the power amplifier 1 is adjusted by a corresponding control signal at its correcting input 12. The radio-frequency signal supplied at the input is amplified in accordance with this adjustment and delivered at the output 13. If the matching changes, for example, due to a change in the spatial arrangement of the antenna 5 with respect to its environment, this leads to additional reflections on the signal path between the output 13 of the power amplifier 1 and the antenna 5. As a result, the active power delivered by the power amplifier drops.

To detect the active power of the radio-frequency signal delivered by the power amplifier 1, the voltage of the delivered radio-frequency signal is then determined at the tap, on the one hand, and supplied to the detector circuit configured as a frequency converter 6 in this embodiment. In parallel, the current of the amplified radio-frequency signal is concurrently detected in the current detector 3, from this a second signal is derived and supplied to the frequency converter 6 at its input 63. From this, the detector circuit determines the active power. For this purpose, the frequency converter 6 in this embodiment multiplies not only the amplitudes of the two signals supplied but also takes into consideration the phase angle. The in-phase components are then mixed down to a DC signal component due to the multiplication. Displaced components can be split into a DC component and a component phase-shifted by 90°. The components shifted in phase by 90° in the signals supplied at the input lead to a partial-signal at twice the fundamental frequency. However, only the DC component is required for the active power of the radio-frequency signal delivered by the power amplifier. In this example the DC component is delivered via the low-pass filter 7 to, for example, an analog/digital converter 8 and converted into a digital value. The digital value is supplied to the control circuit 9 which then adapts the transmitting power of the power amplifier 1 via a control signal.

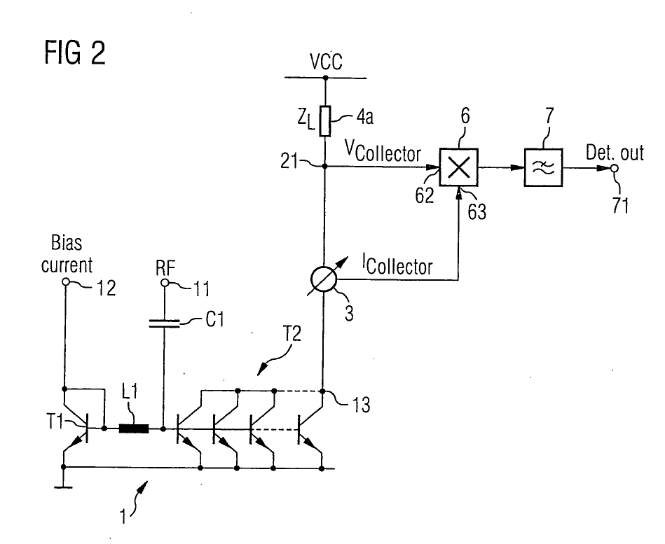

FIG. 2 shows a block diagram with the representation of an output stage of the power amplifier 1 and various elements of the arrangement according to one embodiment of the invention. The output stage of the power amplifier comprises a multiplicity of individual npn-bipolar transistors T2 connected in parallel. The control terminals of the respective bipolar transistors T2 are connected to a current mirror transistor T1 via a coil L1. The control terminal of the current mirror transistor T1 is also connected to its collector terminal. The collector terminal of the current mirror transistor T1 is supplied with a signal for adjusting the idling current. This can be provided, for example, by the control circuit 9 at the correcting input 12. The radio-frequency signal at the input 11 is applied to the control terminals of the transistors T2 of the output stage via a capacitor C1. The coil L1 acts as low-pass filter and prevents crosstalk of the radio-frequency signal component to the current mirror transistor T1.

At the output end, the collectors of the individual output stage transistors T2 are coupled to the output 13 of the power amplifier 1. The output 13 is connected to the element 3 for detection of the collector current I_{collector}. Furthermore, the collector terminal 13 is connected to the tap 21 and to a supply potential terminal VCC via the external load 4a. In this embodiment, the external load 4a comprises the impedance Z_{L} of the matching network and of the antenna. As a general rule, this is a complex impedance.

The collector current I_{collector} and the collector voltage V_{collector} at the tap 21 are supplied as signals to a mixer 6 at its inputs 63 and 62, respectively. At the output end, the mixer 6 is connected to the detector output via a low-pass filter 7.

In the embodiment shown, the collector current I_{collector} is detected and multiplied via the mixer 6 by the collector voltage V_{collector} picked up at the node 21. In this process, not only are the individual amplitudes multiplied by one another but the phase angle is also taken into consideration. In-phase current and voltage components in the radio-frequency output signal form the actual active power. In the mixer 6, half of the in-phase components are mixed to form a DC component DC and half are mixed to form a component at twice the fundamental frequency, due to the multiplication. Phase-shifted components due to a mismatch in the collector current and the collector voltage which correspond to the current and the voltage of the radio-frequency signal can be split into an in-phase component and a component phase-shifted by 90°. The phase-shifted components are completely converted into twice the fundamental frequency.

To determine the active power of the radio-frequency signal, the output of the mixer is connected to the low-pass filter 7 which suppresses the components at higher frequencies. The DC value delivered at the detector output 71 has a ratio with respect to the active power of the radio-frequency signal which is permanently defined.

Apart from the embodiment shown here, of a mixer or a multiplier 6 and the low-pass filter following it, an arrangement can also be used which implements a mixing function and a low-pass function.

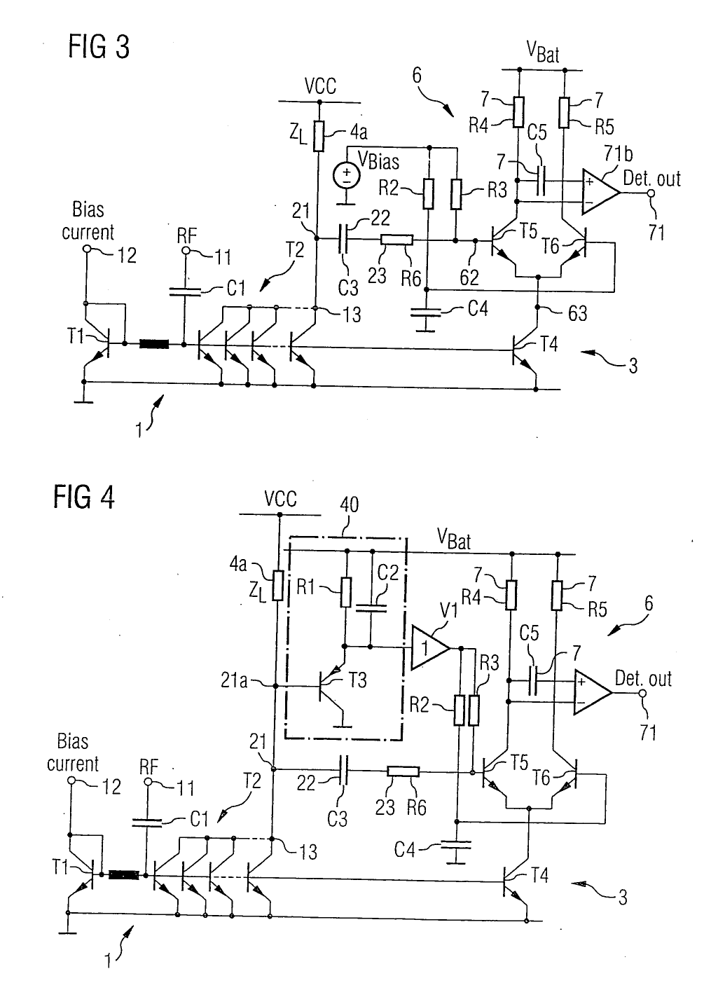

FIG. 3 shows an embodiment of the power amplifier arrangement with a design of the current detector and of the mixer 6. Operationally and functionally identical components carry identical reference symbols. To detect the collector current in the output stage, an additional transistor T4 is connected in parallel in this embodiment. This forms the detector for detecting the collector current. Since the output stage transistors T2 and the transistor T4 have the same base-emitter voltage U_{BE}, the collector current of the transistor T4 is proportional to the collector current of the transistors T2 of the power amplifier. The element 3 for detecting the collector current thus generates a value proportional to the current of the radio-frequency signal delivered by the power amplifier 1. The current delivered by the transistor T4 is therefore a current derived from the current of the radio-frequency signal.

Furthermore, a capacitor C3 22 and a resistor R6 23 are connected to the tap 21. The capacitor C3 and the resistor R6 form a circuit for detecting the collector voltage or, respectively a voltage of the delivered radio-frequency signal. At the same time, the capacitor C3 is also used for AC coupling.

In this embodiment, the mixer 6 is configured as a simple differential amplifier. For this purpose, it comprises two transistors T5 and T6, the emitter terminals of which are jointly connected to one another at a low end and form a first signal input 63 of the mixer. The signal input 63 in turn, is connected to the collector of the transistor T4. The control terminal of the transistor T5 is connected to the resistor R6 and thus to the tap 21. The control terminal of the transistor T6 leads to a ground potential via a capacitor C4, on the one hand, and on the other hand, to a bias voltage source V_{bias} via the resistor R2. The bias voltage source V_{bias} is used for setting the quiescent current or the operating point, respectively, of the differential amplifier. Connecting the base of transistor T6 to the capacitor C4 results in suppression of the radio-frequency voltage.

In the embodiment shown, therefore, the current of the transistor T4 is used as first input signal for the mixer, the second input signal is the collector voltage of the output stage of the power amplifier 1. The two collector outputs of transistors T5 and T6 of the differential amplifier are coupled to one another via a capacitor C5. In addition, each collector terminal is connected to a supply potential V_{bat} via a resistor R4 and R5, respectively.

The resistors R6 and R3 form a voltage divider which reduces the input voltage in order to drive the differential amplifier transistors T5 and T6 linearly. The resistors R4 and R5 together with the capacitor C5, form the low-pass filter. At the output end, the differential signal is converted into a single-ended signal by the amplifier 71b shown. This output signal is delivered at the detector output 71 and supplied for further processing, as may be desired.

FIG. 4 shows another embodiment of the invention. Here too, operationally and functionally identical components carry identical reference symbols. For large output powers, the voltage amplitude at the power amplifier output 13 is so large that the output stage transistors T2 go into saturation. This means that the collector-emitter voltage U_{CE} dropped across the individual transistor output stages T2 becomes relatively small. As a result, the collector current is also reduced, as is the current of the radio-frequency signal. To ensure that the transistor T4 of the current detector 3 supplies an accurate replica of the collector current delivered, it is appropriate to also set the same voltage U_{CE} via its collector and emitter.

The rectifier circuit 40, shown in FIG. 4, is used for this purpose. The circuit 40 is configured as an emitter-follower rectifier and comprises a pnp-bipolar transistor T3 the control terminal of which is connected to the output 13 of the power amplifier 1 via the tap 21a. The collector terminal is connected to the ground potential terminal and the emitter terminal is connected to the supply potential V_{BAT} via a resistor R1 and a capacitor C2 arranged in parallel therewith, on the one hand, and, on the other hand, the emitter terminal of the transistor T3 is also connected to a decoupling amplifier V1. The output of the decoupling amplifier V1, in turn, is connected to the resistors R2 and R3 for driving the operating points of the transistors T5 and T6 of the differential amplifier.

In operation, the emitter-follower rectifier 40 detects the minimum collector voltage of the output stage transistors T2 and thus the minimum voltage component of the radio-frequency signal delivered. This is increased by the emitter-follower rectifier by a diode voltage from the pn junction of the transistor T3. This potential, in turn, is delivered to the bias resistors R2 and R3 via the decoupling amplifier.

When the differential amplifier 6 is in operation, the potential across the base-emitter junction in transistors T5 and T6 of the differential amplifier 6 is again decreased by a diode voltage. As a result, the minimum collector voltages of the output stage transistors T2 and T4 become substantially identical. Accordingly, the output stage transistors T2 of the power amplifier 1 and of the transistor T4 of the current detector 3 now have the same operating conditions. T4 now delivers a current which is essentially proportional to the collector current.

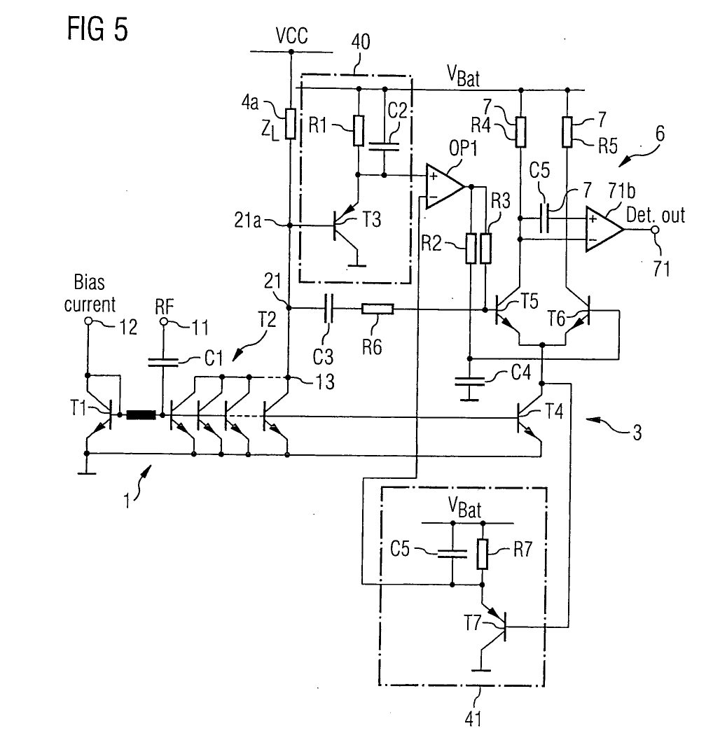

FIG. 5 shows a further improvement. In the embodiment shown, the minimum collector voltage is now measured not only at the output 13 for the output stage transistors T2 for the rectifier circuit 40 but also via a second rectifier circuit 41. In this arrangement, the input of the second rectifier circuit 41, the control terminal of the transistor T7, is connected to the collector terminal of the transistor T4 of the current detector 3. At the output end, the two control circuits 40 and 41 are connected to the inputs of an operational amplifier OP1. The latter compares the two voltages present at the inputs and then adjusts the bias potential via R3 and R2, in such a manner that the minimum collector voltages in each case are substantially identical. The embodiment shown here thus provides for very good adaptations of the minimum collector voltage of the current detector 3 and of the output stage transistors T2 of the power amplifier 1. This avoids the possible uncertainty resulting from the different embodiments of the transistor T3 as pnp-bipolar transistor on the one hand, and of the transistors T5 and T6 as npn-bipolar transistors, on the other hand.

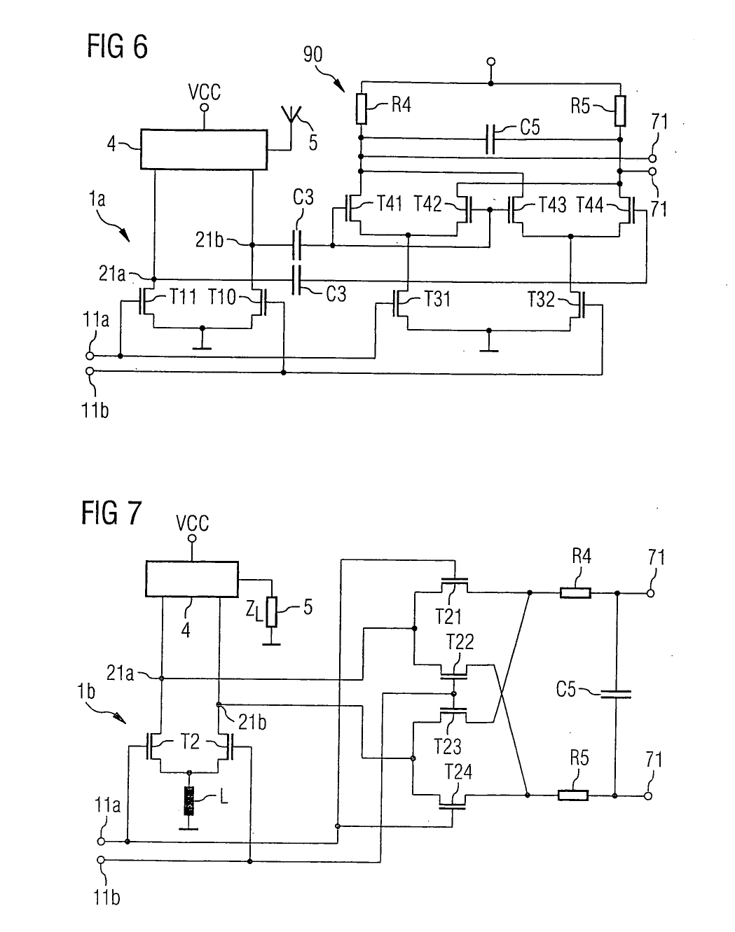

FIG. 6 shows another exemplary embodiment of the power amplifier arrangement. In this embodiment, the power amplifier is designed with field effect transistors in CMOS technology and as a differential amplifier. At the input end, the power amplifier 1a is supplied with a reference signal at inputs 11a and 11b. This is applied to the control terminals of transistors T10 and T11 of the differential amplifier. The two transistors are connected with one terminal to a ground potential at a common low end. The second terminals in each case lead to the matching network 4 and to the supply potential terminal for supplying supply potential VCC. The matching network 4, in turn, is coupled to the antenna 5 for delivering the amplified radio-frequency signal.

In this embodiment, a so-called Gilbert mixer 90 is provided as the detector to detect the current and the voltage, respectively, of the radio-frequency signal delivered by the differential amplifier 1a. This has the advantage that it comprises two voltage inputs. As a result, the voltage of the radio-frequency signal can be delivered directly to an input of the Gilbert mixer 90, on the one hand. In addition, a further voltage, which is supplied to a second input of the Gilbert mixer, can be derived from the current of the radio-frequency signal delivered. Using two voltage inputs also makes it impossible to exchange these and thus to supply the voltage signal derived from the current of the radio-frequency signal to the first input and the voltage signal of the radio-frequency signal to the second input.

The Gilbert mixer 90 shown here contains two first transistors T31 and T32, the control terminals of which are connected to the radio-frequency inputs 11a and 11b of the power amplifier. The radio-frequency signal supplied via the inputs 11a and 11b generates the current component of the radio-frequency signal delivered by the power amplifier during the operation of the power amplifier 1a. Supplying to the two transistors T31 and T32 of the Gilbert mixer thus implements a component for detecting the current of the radio-frequency signal delivered by the power amplifier 1.

In addition, the Gilbert mixer comprises two mixer cells of, in each case, one pair of transistors with the transistors T41, T42 and T43, T44 respectively. The control terminals of the transistors T41 and T44 of the first and second mixer cell are jointly connected to the tap 21a for the voltage component of the radio-frequency signal. The control terminals of transistors T42 and T43 are connected to the second tap 21b of the power amplifier 1a. Furthermore, the outputs of the transistors T43 and T42 are connected to the respective outputs of the mixer cell via a cross coupling. In addition, a low-pass filter in the form of the capacitor C5 and of the resistors R4 and R5 is provided here, too. In addition, the resistors R4 and R5 form a voltage divider for delivering the signal, converted in the mixer cell, to the outputs 71.

FIG. 7 shows a further embodiment. Here, too, a differential output stage 1a is provided in the power amplifier. The output stage 1b shown here is connected with its two output stage transistors T2 to the ground potential via a common low end and a coil L. At the output end, a matching network 4 is provided here, too, to which the antenna 5 is connected as load impedance Z_{L}.

In the embodiment, the detector is formed by a mixer with two cross-coupled mixer cells which in each case have voltage inputs. In this embodiment, the voltage of the differential radio-frequency signal is picked up at the two taps 21a and 21b and supplied directly to the mixer cells of the transistors T21 to T24. In detail, the tap 21a is connected to a first terminal of the transistors T21, T22 of the first mixer cell and the tap 21b is connected to a first terminal of the transistors T23 and T24 of the second mixer cell.

The control terminals of the transistors T22 and T23 are connected to the input 11b. Correspondingly, the control terminals of transistors T21 and T24 are connected to the input 11a for supplying the radio-frequency signal. Here, too, cross coupling and low-pass filtering is effected with the aid of resistors R4, R5 and of capacitor C5. The DC component produced by the frequency conversion and the multiplication can be picked up as differential direct current at taps 71.

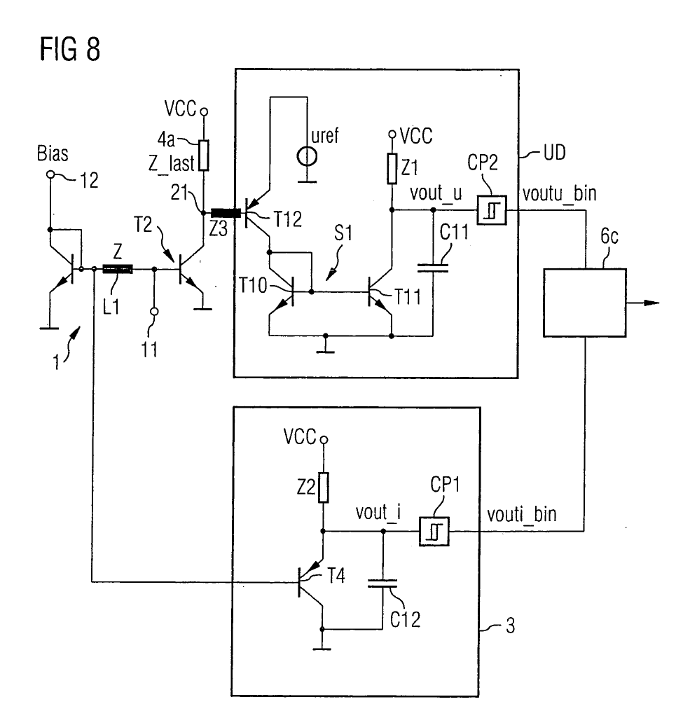

FIG. 8 shows an embodiment of an arrangement for measuring the linearity of a power amplifier 1 with a transistor output stage T2. Operationally and functionally identical components carry identical reference symbols.

Apart from the transmitting output stage transistor T2, the power amplifier 1 contains another transistor of the same type which, together with the transmitting output stage transistor T2 forms a current mirror. The current mirror transistor is configured to supply a bias current for setting the operating point of the power amplifier via the terminal 12.

Furthermore, the collector output of the transistor T2 is connected to a capacitive load Z3 which is used for coupling out the radio-frequency component of the output signal of the power amplifier. This only supplies a part of the radio-frequency signal coupled out to the voltage detector UD. Thus, a DC voltage component can be suppressed by a simple capacitor, in one example. In the present case, the voltage detector UD comprises a first pnp-bipolar transistor for detecting the voltage coupled out.

By using a transistor which is complementary to the transmitting output stage transistor, a current flow only occurs when the collector voltage of the transmitting output stage transistor T2 is below a reference voltage. This is predetermined by the voltage source uref which is connected to the collector terminal of the transistor T12. The reference voltage uref selected is, for example, a voltage which is composed of a saturation voltage usat of the transmitting output stage transistor in addition to a diode voltage of the transistor T12. The saturation voltage usat predetermines the threshold beyond which the transmitting output stage transistor T2 begins to operate in a nonlinear range of its characteristic.

The signal generated by the output voltage at the tap 21 is detected by the transistor T12 and converted into a current. This current is mirrored by a current mirror S1 for further processing. For this purpose, the current mirror S1 contains the transistors T10, T11. The transistor T10 is connected with its collector terminal to the transistor T12 and to its control terminal. The mirror transistor T11 is connected with its emitter to the ground potential and with its collector to a supply potential terminal VCC via a load Z1. The mirrored current signal is converted into a voltage vout_u via the load Z1.

This voltage shows whether the saturation voltage has been reached in the transmitting output stage transistor T2 and the amplifier is thus operating in a nonlinear mode. In addition, a capacitor C11 is connected in parallel with the mirror transistor T11 in order to obtain better evaluation and a more accurate result. From the analog voltage signal vout_u, a binary, and thus logical signal voutu_bin is generated by the threshold detector CP2.

The current is measured by the current detector 3. This contains a transistor T4 which is connected with its collector terminal to a load Z2 and to a supply potential terminal VCC. Its emitter is coupled to the reference potential terminal. The control terminal of the transistor T4 of the current detector 3 is connected to the current mirror of the power amplifier 1.

To mirror the current of the transmitting output stage transistor T2, any ratio of areas between the transistor T2 and the detector transistor T4 can be selected. However, it is expedient if the two transistors T2 and T4 are of the same type and, in addition, have the same input impedance characteristic. The voltage vout_i dropped across the load Z2 is smoothed with the aid of the capacitor C12 connected in parallel between the collector and emitter of the transistor T4. The voltage signal vout_i thus smoothed is applied to a threshold comparator CP1 and compared with a threshold value. In dependence thereon, the comparator delivers a logical signal vouti_bin to the evaluating circuit 6c. The comparator CP1 is used for deciding whether the current through the transistor T2 has exceeded a critical value.

The evaluating circuit, in one example, is constructed with a logical OR gate and evaluates the two binary signals vouti_bin and voutu_bin. As soon as one of the two signals in the present example has a high level and thus represents a logical 1, the evaluating circuit 6c outputs a signal. This indicates that the power amplifier 1 is no longer operating in a linear range of its characteristic and that there may be possible distortions in the amplified output signal.

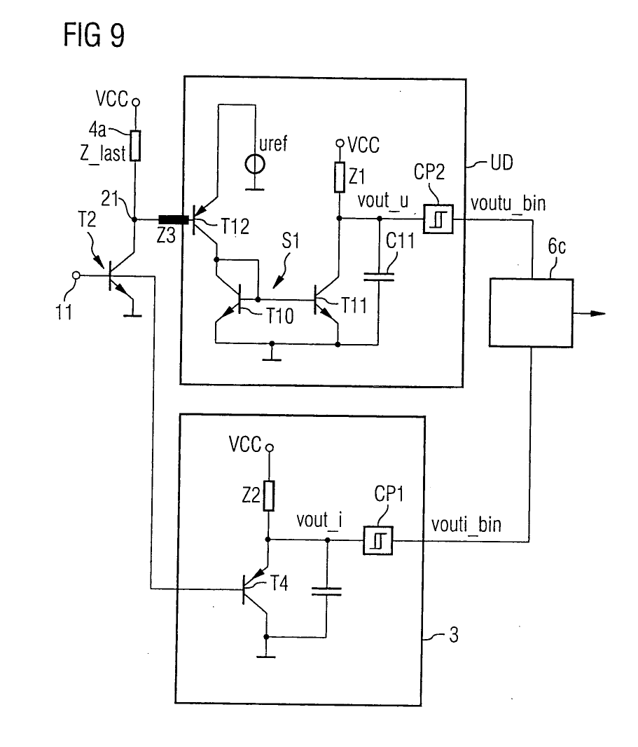

FIG. 9 shows an alternative embodiment for a linearity measurement. Here, too, operationally and functionally similar components carry identical reference symbols. The essential difference with respect to the embodiment in FIG. 8 is in taking the input of the current detector 3 directly from the current of the output stage transistor T2 of the power amplifier 1. This embodiment has the advantage of being able to fully take into consideration any reactions from the load 4a and L1 of the transmitting output stage transistor T2.

Apart from the embodiments with bipolar transistors, shown here, any types of field-effect transistors can also be used. Among other things, this also includes, for example, MOS, CMOS, HEMTS, JFETS or also MESFETS transistors. These field-effect transistors can be used both for constructing the power amplifier and for constructing the current or voltage detector, respectively. Thus, for example, the transistor T4 of the current detector 3 can be designed as field-effect transistor. However, it is also possible to use different technological methods and combine these. Accordingly, the circuit can be implemented in pure nMOS or pMOS technology but also in BiMOS technology or combinations of these, respectively.

It is similarly possible to use the analog voltage signals directly instead of the binary signals vouti_bin or voutu_bin, respectively. This may make it possible to respond flexibly to changes in the operating parameters of the transistor T2. Thus, the risk of operation in a nonlinear range of the characteristic can already be detected in advance and possibly prevented.

The mixer arrangement, particularly the differential amplifier 6 can be implemented easily by means of field-effect transistors. This would allow the signal quality to be improved further since the problems indicated above with respect to pnp-bipolar or npn-bipolar transistors do not occur.

Although the invention has been shown and described with respect to one or more implementations, equivalent alterations and modifications will occur to others skilled in the art based upon a reading and understanding of this specification and the annexed drawings. The invention includes all such modifications and alterations and is limited only by the scope of the following claims. In addition, while a particular feature or aspect of the invention may have been disclosed with respect to only one of several implementations, such feature or aspect may be combined with one or more other features or aspects of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.” Also, the term “exemplary” is merely meant to mean an example, rather than the best. It is also to be appreciated that layers and/or elements depicted herein are illustrated with particular dimensions relative to one another (e.g., layer to layer dimensions and/or orientations) for purposes of simplicity and ease of understanding, and that actual dimensions of the elements may differ substantially from that illustrated herein.

1. A power amplifier arrangement, comprising:
a power amplifier comprising an input configured to receive a first radio-frequency signal, a transistor output stage with a control input which is coupled to the input of the power amplifier, and an output configured to deliver a second radio-frequency signal having a current and a voltage associated therewith;
a first element configured to deliver a first signal derived from the voltage of the second radio-frequency signal;
a second element configured to deliver a second signal derived from the current, concurrently with the voltage of the second radio-frequency signal;
an evaluating circuit coupled to the first element and to the second element, and configured to deliver an evaluation signal based on an evaluation of the first and second derived signals;
wherein the second element is configured to detect a current delivered by the transistor output stage, and the first element is configured to concurrently detect a voltage present at an output of the transistor output stage.

2. The power amplifier arrangement of claim 1, wherein the first element comprises an AC coupling element coupled to the signal output of the power amplifier, and configured to deliver a signal derived from the voltage of the second radio-frequency signal.

3. The power amplifier arrangement of claim 1, wherein the second element comprises a transistor having a control terminal coupled to the input of the power amplifier, and configured to deliver the current derived from the current delivered by the power amplifier.

4. The power amplifier arrangement of claim 3, further comprising a current/voltage converter for current/voltage conversion and a threshold detector configured to compare the converted voltage with a threshold value coupled to an output of the transistor.

5. The power amplifier arrangement of claim 1, wherein the first element comprises a current mirror having an input branch coupled to the output of the power amplifier, and configured to mirror a current derived from the voltage of the second radio-frequency signal, into an output branch thereof that is coupled to a current/voltage converter.

6. The power amplifier arrangement of claim 1, wherein the evaluating circuit is configured to detect a value of the first signal below a first threshold value or to detect a value of the second signal above a second threshold value, or both.

7. The power amplifier arrangement of claim 1, wherein the first and the second element are configured to deliver digital signals, and the evaluating circuit comprises a logic gate, an input of which is coupled to the first and the second elements.

8. The power amplifier arrangement of claim 1, wherein the evaluating circuit comprises a detector circuit configured to detect substantially in-phase components of the first and second signals, and wherein the detector circuit is coupled to the first and to the second elements.

9. The power amplifier arrangement of claim 1, wherein the evaluating circuit comprises a frequency converter and a low-pass filter following the frequency converter, wherein the frequency converter is connected to the second element with a first signal input and to the first element with a second signal input.

10. The power amplifier arrangement of claim 1, wherein the evaluating circuit comprises a differential amplifier with a first and a second transistor, first terminals of which are connected to the second element via a common node, and at least one of the control terminals of the first and of the second transistor of the differential amplifier is coupled to the first element.

11. The power amplifier arrangement of claim 10, wherein second terminals of the first and second transistor of the differential amplifier of the evaluating circuit are coupled to one another via a charge storage element.

12. The power amplifier arrangement of claim 1, wherein the first element comprises a rectifier circuit configured to detect a threshold value and deliver a potential derived therefrom, to the evaluating circuit.

13. The power amplifier arrangement of claim 12, wherein the rectifier circuit comprises a transistor with conductivity type opposite to that of an output transistor of the power amplifier, the control terminal of which is coupled to the output of the power amplifier and an output terminal of which is connected to the evaluating circuit via a decoupling amplifier.

14. The power amplifier arrangement of claim 1, wherein the evaluating circuit comprises a frequency converter having a first and a second voltage input, wherein the first voltage input is coupled to the input of the power amplifier and the second voltage input is coupled to the first element.

15. The power amplifier arrangement of claim 1, further comprising a rectifier circuit connected to a tap between the second element and the evaluating circuit, and configured to detect a threshold value, wherein the rectifier circuit is connected at one terminal to an input of a comparator, and at another terminal to the output of the power amplifier, and wherein the rectifier circuit comprises an output coupled to a node between the first element and the evaluating circuit.

16. A method for determining a performance parameter in a power amplifier, comprising:
providing a signal to be amplified;
amplifying the signal, the amplified signal having a current and a voltage associated therewith;
detecting a voltage derived from the voltage of the amplified signal at a point in time;
detecting a first signal derived from the current of the amplified signal at approximately the same point in time; and
combining the detected voltage and the detected first signal and generating an evaluation signal based thereon.

17. The method of claim 16, wherein combining comprises in-phase multiplying of the detected first signal and the detected voltage.

18. The method of claim 17, wherein the in-phase multiplying further comprises:
generating a second signal from the detected voltage;
mixing the first and second signal;
filtering the mixed signal; and
detecting a DC component in the mixed signal.

19. The method of claim 16, wherein combining comprises:
comparing the detected voltage with a first threshold value;
comparing the detected first signal with a second threshold value; and
generating the evaluation signal when the detected voltage drops below the first threshold value or the detected first signal exceeds the second threshold value.
